(19) United States
(12) Patent Application Publication
(10) Pub. No.: US 2022/0045664 A1
(43) Pub. Date: Feb. 10, 2022

(54) RADIO FREQUENCY (RF) FILTER WITH INCREASED SHUNT RESONATOR COUPLING COEFFICIENT

(71) Applicant: RF360 EUROPE GMBH, Munchen (DE)

(72) Inventor: Thomas Bain POLLARD, Longwood, FL (US)

(21) Appl. No.: 16/989,410

(22) Filed: Aug. 10, 2020

(51) Int. Cl. H03H 9/64; H03H 9/54

(52) U.S. Cl. CPC H03H 9/6433; H03H 9/542

(57) ABSTRACT

Certain aspects of the present disclosure generally relate to a filter, such as an acoustic resonator filter. An example filter generally includes a first series resonator coupled between a first port of the filter and a second port of the filter, the first series resonator including a first piezoelectric layer disposed between a first electrode and a second electrode of the first series resonator. The filter also includes a first shunt resonator coupled between a first node of the filter and a reference potential node of the filter, the first shunt resonator including a second piezoelectric layer disposed between a third electrode and a fourth electrode of the first shunt resonator. The first node is coupled between the two ports, and the second piezoelectric layer's thickness is greater than the first piezoelectric layer's thickness.

### BACKGROUND

### Field of the Disclosure

Certain aspects of the present disclosure generally relate to electronic components and, more particularly, a radio frequency (RF) filter.

### Description of Related Art

A resonator is a device that exhibits resonance or resonant behavior. That is, the resonator may naturally oscillate with greater amplitude at some frequencies, called resonant frequencies, than at other frequencies. The oscillations in a resonator can be either electromagnetic or mechanical (including acoustic). Resonators may be used to generate waves of specific frequencies and/or to select specific frequencies from a signal. Resonators may be implemented with piezoelectric material between two electrodes, and multiple resonators may be combined in various circuit combinations to be implemented as filters of various types.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include a filter with the desired frequency performance characteristics, but with reduced power consumption and/or improved linearity.

Certain aspects of the present disclosure provide a filter. The filter generally includes a first series resonator coupled between a first port of the filter and a second port of the filter, the first series resonator including a first piezoelectric layer disposed between a first electrode and a second electrode of the first series resonator. The filter may also include a first shunt resonator coupled between a first node of the filter and a reference potential node of the filter, the first shunt resonator including a second piezoelectric layer disposed between a third electrode and a fourth electrode of the first shunt resonator. The first node may be coupled between the first port and the second port, and a thickness of the second piezoelectric layer may be greater than a thickness of the first piezoelectric layer.

Certain aspects of the present disclosure provide a method for filtering an input signal. The method generally includes receiving the input signal at a first port of a filter and generating a filtered version of the input signal at a second port of the filter. The filter generally includes a first series resonator coupled between a first port of the filter and a second port of the filter, the first series resonator including a first piezoelectric layer disposed between a first electrode and a second electrode of the first series resonator. The filter may also include a first shunt resonator coupled between a first node of the filter and a reference potential node of the filter, the first shunt resonator including a second piezoelectric layer disposed between a third electrode and a fourth electrode of the first shunt resonator. The first node may be coupled between the first port and the second port, and a thickness of the second piezoelectric layer may be greater than a thickness of the first piezoelectric layer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIG. 4 illustrates an example radio frequency (RF) filter having a shunt resonator with a higher coupling coefficient than a series resonator, in accordance with certain aspects of the present disclosure.

FIG. 5 is a graph of an example frequency response of an example RF filter in terms of impedance, in accordance with certain aspects of the present disclosure.

FIG. 6 is a flow diagram depicting example operations for filtering a signal with an RF filter, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a radio frequency (RF) filter with a shunt resonator having a piezoelectric layer that is thicker than a piezoelectric layer of a series resonator. As described in more detail herein, the shunt and series resonators may each include a piezoelectric layer, each with a different thickness such that a resonant frequency of the shunt resonator is less than a resonant frequency of the series resonator. Additionally, the series and shunt resonators may be implemented in multiple stages of an RF filter, for example, to increase the roll-off associated with a transfer function of the RF filter.

### Example Wireless Communication System and Components

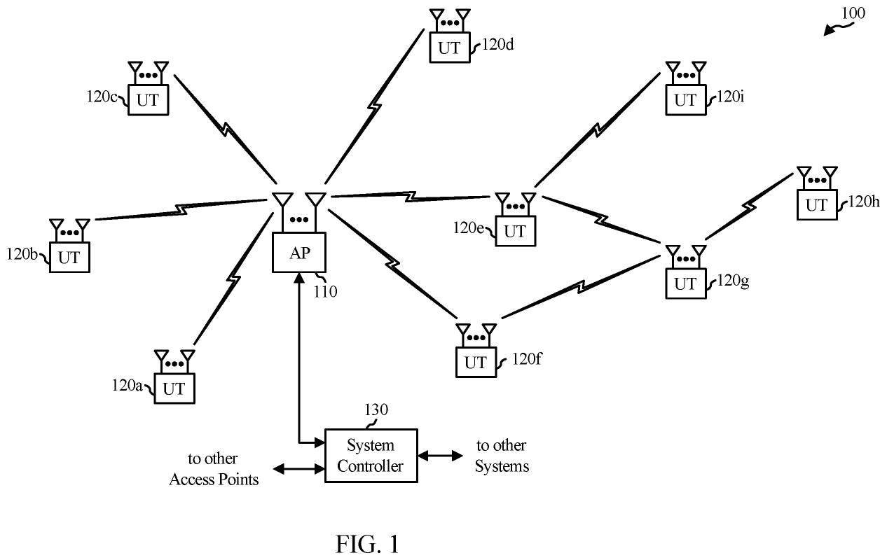

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In certain aspects of the present disclosure, the access point 110 and/or user terminal 120 may include an RF filter with a shunt resonator having a piezoelectric layer that is thicker than a piezoelectric layer of a series resonator, as described in more detail herein.

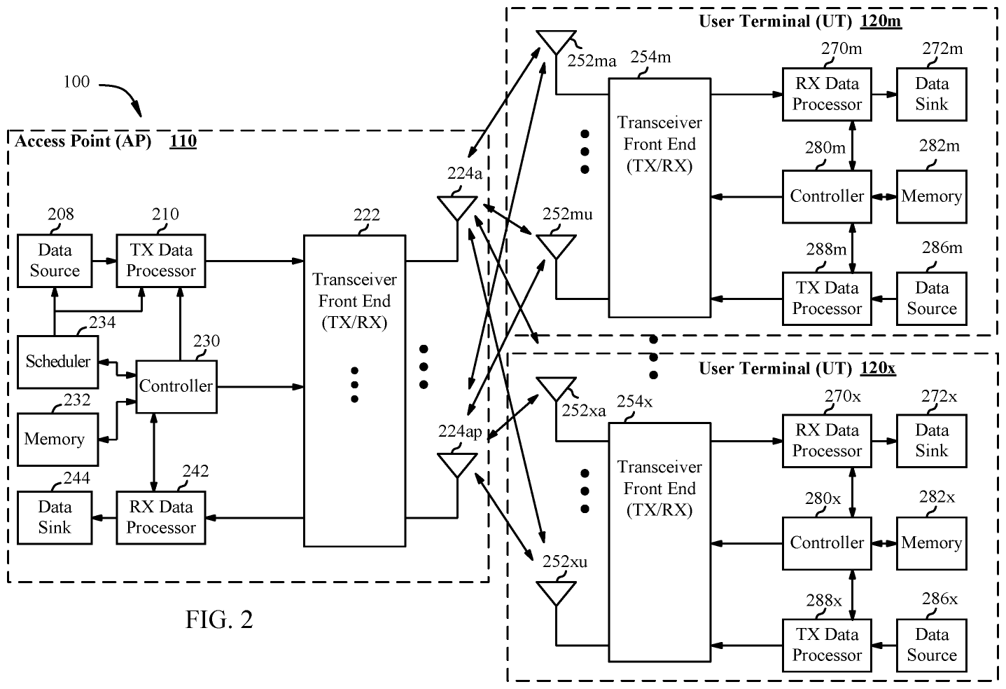

FIG. 2 shows a block diagram of access point 110 and two user terminals 120m and 120x in the wireless communications system 100. Access point 110 is equipped with Naₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Naₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing. The transceiver front end (TX/RX) 222 of access point 110 and/or transceiver front end 254 of user terminal 120 may include an RF filter with a shunt resonator having a piezoelectric layer that is thicker than a piezoelectric layer of a series resonator, as described in more detail herein.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

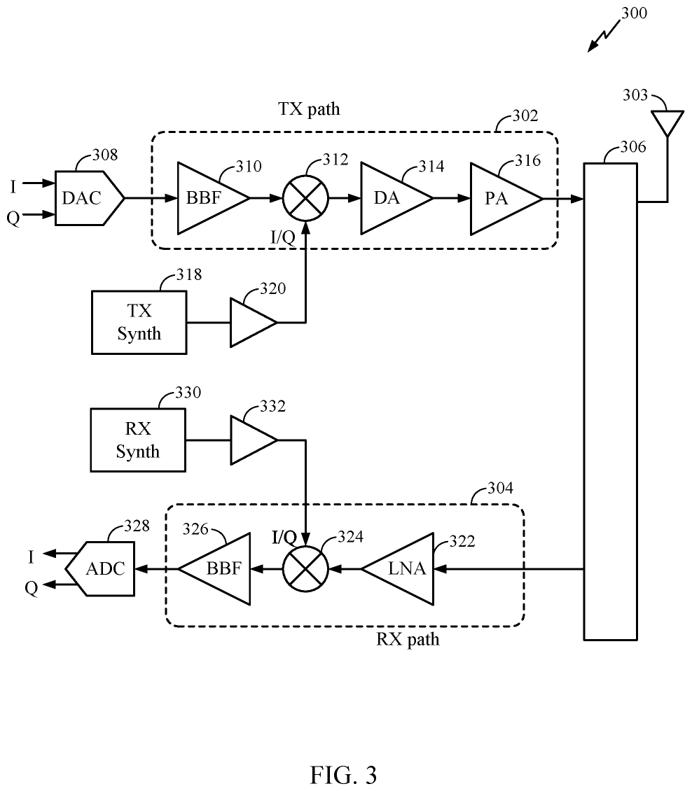

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, a filter as further described herein, and/or the like. In some examples, the interface 306 may include an RF filter with a shunt resonator having a piezoelectric layer that is thicker than a piezoelectric layer of a series resonator, as described in more detail herein.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

Although the block diagram of FIG. 3 depicts the transceiver front end 300 as a single conversion transceiver utilizing quadrature modulation and demodulation, aspects of the present disclosure are not limited to this configuration. For example, one or more of the TX path 302 or the RX path can be configured as a superheterodyne configuration utilizing more than one frequency conversion. Similarly, the transceiver front end 300 is illustrated with quadrature modulation and demodulation, but may alternatively be implemented with polar modulation/demodulation. In a polar modulation configuration, the TX path 302 would receive phase and amplitude signals from a baseband module and use these signals to phase and amplitude modulate a constant-envelope RF or intermediate frequency (IF) signal.

While it is desirable for the output of an LO to remain stable in frequency, tuning the LO to different frequencies typically entails using a variable-frequency oscillator, which may involve compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324.

### Example RF Filter with Greater Shunt Resonator Piezoelectric Layer Thickness

Certain aspects of the present disclosure generally relate to a radio frequency (RF) filter with a shunt resonator having a piezoelectric layer that is thicker than a piezoelectric layer of a series resonator. For example, the thickness of the piezoelectric layers of the shunt and series resonators may be configured such that a resonant frequency of the shunt resonator is less than a resonant frequency of the series resonator to implement a bandpass filter. In some examples, the shunt resonator may have a higher coupling coefficient (k²) compared to the series resonator. Additionally, certain aspects may provide series and shunt resonators implemented in multiple stages of the RF filter to increase the roll-off slope—and hence, enhance the frequency selectivity—of the RF filter.

Currently, many emerging fifth-generation (5G) frequency bands specify increased relative bandwidth, higher center frequencies, and higher power density compared to previous generations. Piezoelectric-based acoustic filter technologies may be implemented to accommodate such characteristics, but traditional acoustic filters may not be able to fulfill all of the constraints of the bands for 5G systems. One such band with such constraints may be 3300 MHz-4200 MHz with a relative bandwidth of about 24%, where relative bandwidth is the ratio of a bandwidth being considered (e.g., a desired bandwidth for the filter) to a specific reference bandwidth (e.g., bandwidth between frequencies at which there is an attenuation of 3 dB). One of the most widely implemented filters from previous generations is a filter designed for band 41, which operates between 2496-2690 MHz with a relative bandwidth of about 7.5%. An increased relative bandwidth may be implemented with acoustic resonators that present relatively high electromechanical-coupling (k²) to enable improved filter behavior over the entire relative bandwidth of the filter.

In addition, wider bandwidth filters may be implemented by detuning the resonance or anti-resonance frequencies of the series resonator or shunt resonator in order to achieve sharp filter transitions (e.g., increased relative bandwidth and/or increased roll-off) at both the upper band edges and the lower band edges. To accommodate the desired bandwidth and provide for appropriate k², coupling enhancement techniques may be used. For example, external elements (e.g., inductors) may be implemented in series with a resonator (e.g., a shunt resonator). However, such external elements typically have a lower effective quality factor (Q), and thus may increase filter insertion loss (IL).

In the case of bulk acoustic wave (BAW) technology, conventional methods of resonator detuning may be achieved by applying additional mass loading to the shunt resonator on a top surface of the piezoelectric layer in order to form a thicker top electrode, or thicker silicon nitride passivation layer thickness. That is, detuning the shunt resonator may be accomplished by making the thicknesses of the top electrodes (or the bottom electrodes) of the series and shunt resonators different. For example, the series resonator stack may have top and bottom electrodes of similar thickness, while the shunt resonator stack may have top and bottom electrodes of different thicknesses. However, implementing resonators with increased electrode thickness may result in additional mass loading of the shunt resonator. As the detune loading increases, the effective electromechanical coupling of the detuned device may become compromised. In other words, the series resonator and the shunt resonator may have substantially different electromechanical coupling coefficients.

In addition, if detuning is performed using the electrodes, the effective top electrode conductivity may be different between the series and shunt resonators. As a result, the top electrode of the series resonator may be thinned, resulting in undesired ohmic losses in the filter. In terms of operating at higher frequencies, thinning electrodes in the resonator and reduction of the resonator area may help achieve similar filter impedance characteristics between the shunt and series resonators. However, the device may still experience reduced power durability and reduced device linearity, as well as increased ohmic losses.

Accordingly, certain aspects of the present disclosure provide for detuning of shunt resonators by increasing the piezoelectric layer thickness of the shunt resonator such that a resonant frequency of the shunt resonator of a filter is less than a resonant frequency of a series resonator of the filter. Certain aspects provide reduced power consumption of a device in which the resonators are implemented, as well as improved linearity, as compared to conventional implementations. In addition, certain aspects provide balancing of the top electrode electrical conductivity between the series and shunt resonators of a filter, as described in more detail herein.

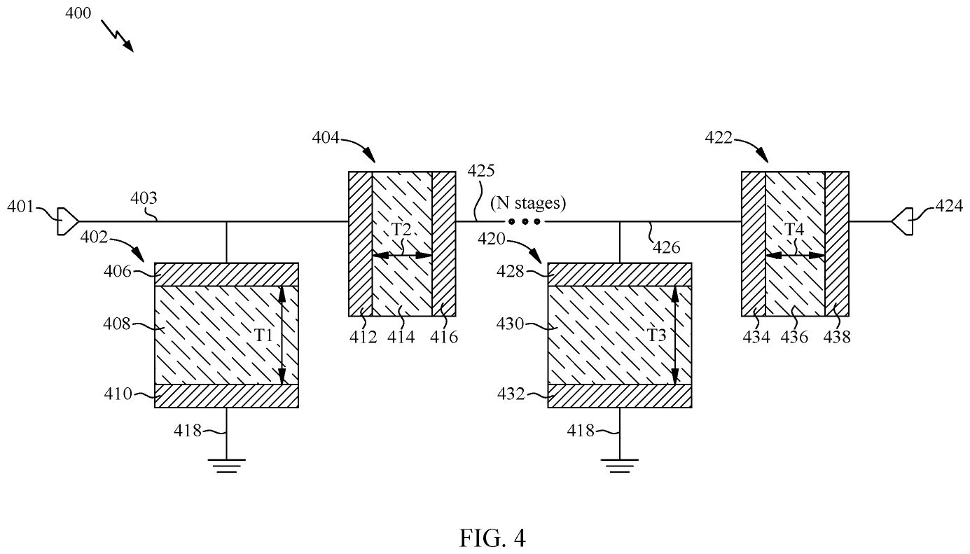

FIG. 4 illustrates an RF filter 400 with a shunt resonator which has a piezoelectric layer with a thickness configured for detuning of the shunt resonator, in accordance with certain aspects of the present disclosure. As shown, the RF filter 400 may include a shunt resonator 402 and a series resonator 404 in a first filter stage. As illustrated, the shunt resonator 402 may be coupled between an input port 401 of the RF filter 400 and a reference potential node 418 (e.g., electrical ground as shown). The series resonator 404 may be coupled between the input port 401 and node 425.

The shunt resonator 402 may include a piezoelectric layer 408 disposed between electrodes 406, 410, and the series resonator 404 may include a piezoelectric layer 414 disposed between electrodes 412, 416. As shown, the electrodes 406, 412 may be coupled to the input port 401, the electrode 410 may be coupled to the reference potential node 418, and the electrode 416 may be coupled to the node 425. In certain aspects, each of the electrodes 406, 410, 412, 416 may have the same thickness, whereas in other aspects at least one of the electrodes 406, 410, 412, 416 may have a different thickness than other electrodes in this group. In certain aspects, each of the electrodes 406, 410, 412, 416 may be made of molybdenum (Mo), tungsten (W), aluminum (Al)-copper (Cu) alloy, aluminum nitride (AlN), titanium (Ti), titanium tungsten (TiW), titanium nitride (TiN), a combination thereof, or any other suitable material. In certain aspects, the piezoelectric layers 408, 414 may be made of scandium (Sc)-doped aluminum nitride (AlN) or any other suitable material.

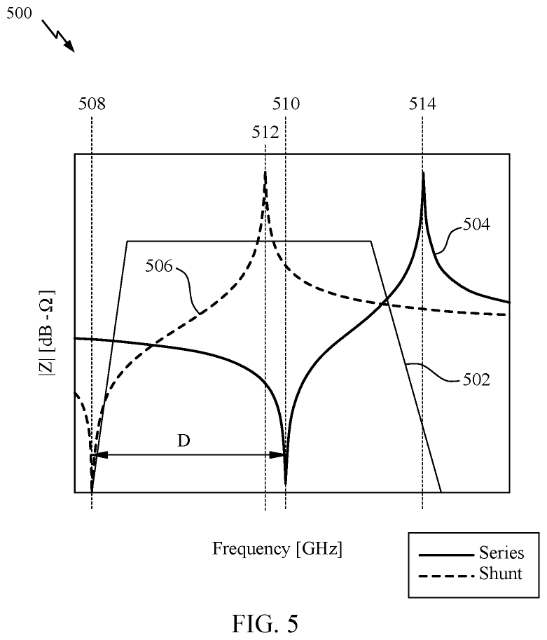

In certain aspects of the present disclosure, the thickness of the piezoelectric layers of the shunt and series resonators may be configured such that a resonant frequency of the shunt resonator is less than a resonant frequency of the series resonator (e.g., to implement a bandpass filter). For example, as shown, the piezoelectric layer 408 may have a thickness T1, and the series resonator may have a thickness T2, where T1 is configured to be greater than T2. As used herein, the thickness of a first piezoelectric layer is considered to be greater than a thickness of a second piezoelectric layer if the thickness of the first piezoelectric layer is greater than the thickness of the second piezoelectric layer by 10 nm. In other words, the thickness T1 of the shunt resonator 402 may be configured to detune the shunt resonator 402 such that a resonant frequency of the shunt resonator 402 is less than a resonant frequency of the series resonator 404, as described further herein with respect to FIG. 5.

FIG. 5 illustrates a graph 500 of a frequency response 502 of the RF filter 400 in terms of impedance (Z), in accordance with certain aspects of the present disclosure. For example, the frequency response 502 may be characteristic of a bandpass filter frequency response. As shown, the series resonator 404 may have a series resonator frequency response 504, and the shunt resonator 402 may have a shunt resonator frequency response 506. The resonant frequency 508 of the shunt resonator may be detuned by configuring the thickness T1 of the piezoelectric layer 408 to be greater than the thickness T2 of the piezoelectric layer 414. In other words, the detuning of the shunt resonator 402 may result in the resonant frequency 508 of the shunt resonator 402 to be less than the resonant frequency 510 of the series resonator frequency response 504 by a detuning frequency offset (D).

The k² of the shunt resonator 402 may be associated with a frequency difference between the resonant frequency 508 and the anti-resonant frequency 512 of the shunt resonator frequency response 506. Similarly, the k² of the series resonator 404 may be associated with a frequency difference between the resonant frequency 510 and an anti-resonant frequency 514 of the series resonator frequency response 504. In certain aspects, the shunt resonator 402 may have a greater k² than the series resonator 404, as described herein, by detuning the shunt resonator, while having a relatively similar conductivity as the series resonator 404 (e.g., when the thicknesses and surface areas of the corresponding electrodes are the same between the shunt and series resonators, yielding similar conductivity).

In certain aspects, detuning of the shunt resonator 402 may be accomplished with little to no impact to the electrical conductivity of the electrode 406 of the shunt resonator 402 because the detuning of the shunt resonator 402 may be performed by configuring the piezoelectric layer 408 thickness T1, as opposed to adjusting electrode thickness. While setting the thickness T1 of the piezoelectric layer 408 to be greater than the thickness T2 of the piezoelectric layer 414 may result in a lower conductivity (e.g., as compared to implementations where detuning is performed by increasing electrode thickness), k² of the shunt resonator 402 may be increased. In particular, the increased k² of the shunt resonator 402 may be attained without implementing any external inductors to artificially increase the k² of the shunt resonator 402. Furthermore, increasing the thickness of the piezoelectric layer 408 instead of implementing external inductors may allow the shunt resonator 402 to have an increased k² without increasing filter insertion loss.

Referring back to FIG. 4, the RF filter 400 may be implemented with multiple filter stages. For example, the RF filter 400 may include a shunt resonator 420 and a series resonator 422 in a second filter stage. The shunt resonator 420 and the series resonator 422 may be similar to the shunt resonator 402 and the series resonator 404, respectively. For example, the shunt resonator 420 may include a piezoelectric layer 430 between electrodes 428, 432. The piezoelectric layer 430 may have a thickness T3. As shown, the shunt resonator 420 may be coupled between the reference potential node 418 and a node 426 between the series resonator 404 and the series resonator 422. Nodes 425 and 426 may be the same node in instances where the filter is composed of two stages. The series resonator 422 may be coupled between the node 426 and the output port 424. The series resonator 422 may include a piezoelectric layer 436 between electrodes 434, 438. The piezoelectric layer 436 may have a thickness T4. Although only two filter stages of series and shunt resonators are shown, the RF filter may include N filter stages of series and shunt resonators coupled in a similar fashion as those depicted, where N is an integer equal to or greater than 1. In certain aspects, including N stages of series and shunt resonators may provide for a sharper filter response for the RF filter 400. The thickness of the piezoelectric layers of resonators in each of the N stages may be configured for detuning, similar to techniques described with respect to the shunt resonator 402 and the series resonator 404. Although not shown, each of the shunt resonators 402, 420 and the series resonators 404, 422 may be implemented as a solidly mounted resonator (SMR) with an acoustic mirror or a film bulk acoustic resonator (FBAR) with a cavity as a bottommost layer and a dielectric passivation layer as a topmost layer.

In certain aspects, each filter stage in the N filter stages of the filter may include a series resonator followed by a shunt resonator. Conceptually speaking, port 424 in the filter 400 of FIG. 4 could be considered as the input port, and port 401 could be considered as the output port to achieve this alternative type of filter.

### Example Filtering Operations

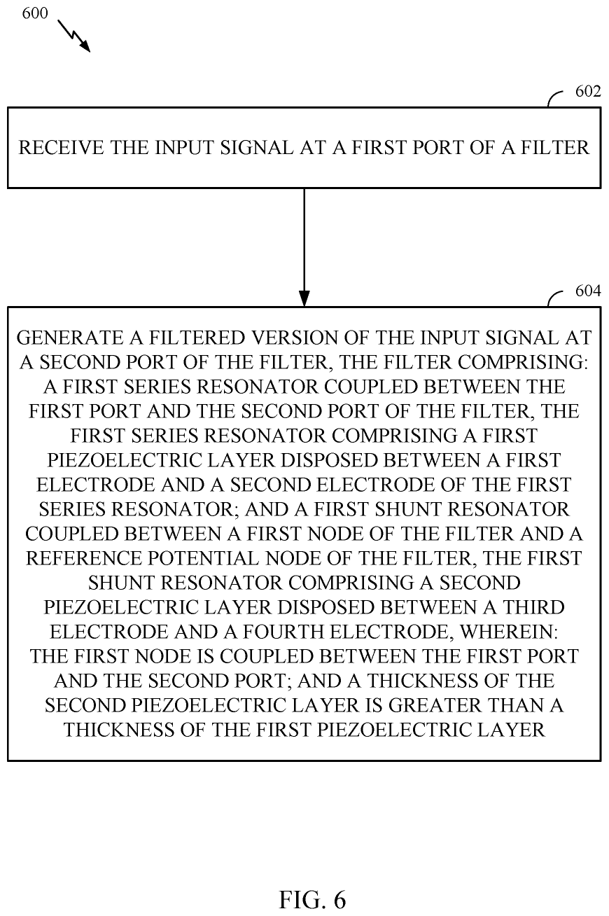

FIG. 6 is a flow diagram depicting example operations 600 for filtering an input signal, in accordance with certain aspects of the present disclosure. The operations 600 may be performed by an RF filter, such as the RF filter 400 depicted in FIG. 4.

The operations 600 begin, at block 602, with the RF filter receiving the input signal at a first port (e.g., the input port 401) of the filter. At block 604, the RF filter generates a filtered version of the input signal at a second port (e.g., the output port 424) of the filter. The filter includes a first series resonator (e.g., the series resonator 404) coupled between the first port and the second port of the filter. The first series resonator may include a first piezoelectric layer (e.g., the piezoelectric layer 414) disposed between a first electrode (e.g., the electrode 412) and a second electrode (e.g., the electrode 416) of the first series resonator. The RF filter may further include a first shunt resonator (e.g., the shunt resonator 402) coupled between a first node (e.g., node 403) of the filter and a reference potential node (e.g., the reference potential node 418) of the filter, where the first shunt resonator includes a second piezoelectric layer (e.g., the piezoelectric layer 408) disposed between a third electrode (e.g., the electrode 406) and a fourth electrode (e.g., the electrode 410). A thickness (e.g., the thickness T1) of the second piezoelectric layer may be greater than a thickness (e.g., the thickness T2) of the first piezoelectric layer (e.g., such that a resonant frequency of the first shunt resonator is less than a resonant frequency of the first series resonator).

The first node may be coupled between the first port and the second port. For example, the first node may be connected to the first port.

In certain aspects, the first series resonator may have a first coupling coefficient, and the first shunt resonator may have a second coupling coefficient that is greater than the first coupling coefficient.

In certain aspects, the first electrode, the second electrode, the third electrode, and the fourth electrode may have the same thickness. In other cases, only the third electrode and the fourth electrode have the same thickness. Alternatively, the thickness of the third electrode may be different from the thickness of the fourth electrode. In certain aspects, each of the first electrode, the second electrode, the third electrode, and the fourth electrode may include Mo, W, Al—Cu alloy, AlN, Ti, TiW, TiN, or a combination thereof.

In some examples, the RF filter may further include a second series resonator (e.g., the series resonator 422) coupled between the first series resonator and the second port of the filter. The second series resonator may comprise a third piezoelectric layer (e.g., the piezoelectric layer 436) disposed between a fifth electrode (e.g., the electrode 434) and a sixth electrode (e.g., the electrode 438) of the second series resonator. The filter may also include a second shunt resonator (e.g., the shunt resonator 420) coupled between a second node (e.g., the node 426) and the reference potential node. The second shunt resonator may include a fourth piezoelectric layer (e.g., the piezoelectric layer 430) disposed between a seventh electrode (e.g., the electrode 428) and an eighth electrode (e.g., the electrode 432), where the second node is coupled between the first port and the second port. A thickness (e.g., the thickness T3) of the fourth piezoelectric layer may be greater than a thickness (e.g., the thickness T4) of the third piezoelectric layer (e.g., such that a resonant frequency of the second shunt resonator is less than a resonant frequency of the second series resonator). In some cases, the second node may be coupled between the first series resonator and the second series resonator. In some aspects, the second node may be connected to the second port of the filter.

In certain aspects, the second series resonator may have a third coupling coefficient, and the second shunt resonator may have a fourth coupling coefficient that is greater than the third coupling coefficient.

In some examples, the thickness of the fourth piezoelectric layer may be different from the thickness of the second piezoelectric layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A filter comprising:
a first series resonator coupled between a first port of the filter and a second port of the filter, the first series resonator comprising a first piezoelectric layer disposed between a first electrode and a second electrode of the first series resonator; and
a first shunt resonator coupled between a first node of the filter and a reference potential node of the filter, the first shunt resonator comprising a second piezoelectric layer disposed between a third electrode and a fourth electrode of the first shunt resonator, wherein:
the first node is coupled between the first port and the second port of the filter; and
a thickness of the second piezoelectric layer is greater than a thickness of the first piezoelectric layer.

2. The filter of claim 1, wherein the first series resonator has a first coupling coefficient, and wherein the first shunt resonator has a second coupling coefficient that is greater than the first coupling coefficient.

3. The filter of claim 1, wherein the first electrode, the second electrode, the third electrode, and the fourth electrode have same thickness.

4. The filter of claim 1, wherein the third electrode and the fourth electrode have same thickness.

5. The filter of claim 1, wherein a thickness of the third electrode is different from a thickness of the fourth electrode.

6. The filter of claim 1, wherein the first node is connected to the first port of the filter.

7. The filter of claim 1, wherein each of the first piezoelectric layer and the second piezoelectric layer comprises scandium (Sc)-doped aluminum nitride (AlN).

8. The filter of claim 1, wherein each of the first electrode, the second electrode, the third electrode, and the fourth electrode comprises molybdenum (Mo), tungsten (W), aluminum (Al)-copper (Cu) alloy, AlN, titanium (Ti), titanium tungsten (TiW), titanium nitride (TiN), or a combination thereof.

9. The filter of claim 1, further comprising:
a second series resonator coupled between the first series resonator and the second port of the filter, the second series resonator comprising a third piezoelectric layer disposed between a fifth electrode and a sixth electrode of the second series resonator; and
a second shunt resonator coupled between a second node of the filter and the reference potential node of the filter, the second shunt resonator comprising a fourth piezoelectric layer disposed between a seventh electrode and an eighth electrode of the second shunt resonator, wherein the second node is coupled between the first port and the second port of the filter and wherein a thickness of the fourth piezoelectric layer is greater than a thickness of the third piezoelectric layer.

10. The filter of claim 9, wherein the second node is coupled between the first series resonator and the second series resonator.

11. The filter of claim 9, wherein the second node is connected to the second port of the filter.

12. The filter of claim 9, wherein the second series resonator has a third coupling coefficient and wherein the second shunt resonator has a fourth coupling coefficient that is greater than the third coupling coefficient.

13. The filter of claim 9, wherein the thickness of the fourth piezoelectric layer is different from the thickness of the second piezoelectric layer.

14. The filter of claim 9, wherein a thickness of the seventh electrode is different from a thickness of the eighth electrode.

15. The filter of claim 9, wherein the fifth electrode, the sixth electrode, the seventh electrode, and the eighth electrode have same thickness.

16. The filter of claim 9, wherein each of the third piezoelectric layer and the fourth piezoelectric layer comprises scandium (Sc)-doped aluminum nitride (AlN).

17. The filter of claim 9, wherein each of the fifth electrode, the sixth electrode, the seventh electrode, and the eighth electrode comprises molybdenum (Mo).

18. A method for filtering an input signal, comprising:
receiving the input signal at a first port of a filter; and
generating a filtered version of the input signal at a second port of the filter, the filter comprising:
a first series resonator coupled between the first port and the second port of the filter, the first series resonator comprising a first piezoelectric layer disposed between a first electrode and a second electrode of the first series resonator; and
a first shunt resonator coupled between a first node of the filter and a reference potential node of the filter, the first shunt resonator comprising a second piezoelectric layer disposed between a third electrode and a fourth electrode of the first shunt resonator, wherein:
the first node is coupled between the first port and the second port of the filter; and
a thickness of the second piezoelectric layer is greater than a thickness of the first piezoelectric layer.

19. The method of claim 18, wherein the first series resonator has a first coupling coefficient, and wherein the first shunt resonator has a second coupling coefficient that is greater than the first coupling coefficient.

20. The method of claim 18, wherein the first electrode, the second electrode, the third electrode, and the fourth electrode have same thickness.

21. The method of claim 18, wherein the third electrode and the fourth electrode have same thickness.

22. The method of claim 18, wherein a thickness of the third electrode is different from a thickness of the fourth electrode.

23. The method of claim 18, wherein the first node is connected to the first port of the filter.

24. The method of claim 18, wherein each of the first piezoelectric layer and the second piezoelectric layer comprises scandium (Sc)-doped aluminum nitride (AlN).

25. The method of claim 18, wherein each of the first electrode, the second electrode, the third electrode, and the fourth electrode comprises molybdenum (Mo), tungsten (W), aluminum (Al)-copper (Cu) alloy, AlN, titanium (Ti), titanium nitride (TiN), titanium tungsten (TiW), or a combination thereof.

26. The method of claim 18, wherein the filter further comprises:
a second series resonator coupled between the first series resonator and the second port of the filter, the second series resonator comprising a third piezoelectric layer disposed between a fifth electrode and a sixth electrode of the second series resonator; and
a second shunt resonator coupled between a second node of the filter and the reference potential node of the filter, the second shunt resonator comprising a fourth piezoelectric layer disposed between a seventh electrode and an eighth electrode of the second shunt resonator, wherein the second node is coupled between the first port and the second port of the filter and wherein a thickness of the fourth piezoelectric layer is greater than a thickness of the third piezoelectric layer.

27. The method of claim 26, wherein the second node is coupled between the first series resonator and the second series resonator.

28. The method of claim 26, wherein the second node is connected to the second port of the filter.

29. The method of claim 26, wherein the second series resonator has a third coupling coefficient and wherein the second shunt resonator has a fourth coupling coefficient that is greater than the third coupling coefficient.

30. The method of claim 26, wherein the thickness of the fourth piezoelectric layer is different from the thickness of the second piezoelectric layer.
